(19) United States
(12) Patent Application Publication
(10) Pub. No.: US 2026/0300595 A1
(43) Pub. Date: Oct. 1, 2026

(54) FLOOR PLANNER FOR LAYOUT AREA REDUCTION

(71) Applicant: QUALCOMM Incorporated, San Diego, CA (US)

(72) Inventors: Mehran BAKHSHIANI, San Diego, CA (US); Pierre-David LETOURNEAU, Austin, TX (US); Bhushan Shanti ASURI, San Diego, CA (US); Matthew Harper LANGSTON, Beacon, NY (US); Maulin BHAGAT, Bangalore (IN); Satya Krishna IDURY, Bengaluru (IN); Dalton James JONES, Cupertino, CA (US)

(21) Appl. No.: 19/089,733

(22) Filed: Mar. 25, 2025

(51) Int. Cl. G06F 30/392

(52) U.S. Cl. CPC G06F 30/392

(57) ABSTRACT

Certain aspects of the present disclosure are directed towards techniques and apparatus for layout generation. An example method generally includes: receiving one or more constraints associated with a layout of circuit blocks, the one or more constraints including at least one of a level of isolation or a distance between at least two of the circuit blocks; parsing the one or more constraints to generate input data for a layout generation component based on the one or more constraints; generating one or more parameters of the layout based on the input data via the layout generation component; and output the one or more parameters.

### TECHNICAL FIELD

Certain aspects of the present disclosure generally relate to electronic design techniques and, more particularly, to techniques and apparatus for generating a layout for circuit blocks.

### BACKGROUND

Circuit layouts refer to the physical design and arrangement of electronic components on a printed circuit board (PCB) or within a semiconductor chip (e.g., integrated circuit (IC)). The layout may be designed such that electrical signals flow between components while reducing interference, noise, and signal degradation, for example. The layout may include the arrangement of various circuit blocks. A circuit block generally refers to a group of components designed to perform a specific task or operation.

### SUMMARY

The systems, methods, and devices of the disclosure each have several aspects, no single one of which is solely responsible for its desirable attributes. Without limiting the scope of this disclosure as expressed by the claims that follow, some features are discussed briefly below. After considering this discussion, and particularly after reading the section entitled “Detailed Description,” one will understand how the features of this disclosure provide the advantages described herein.

Certain aspects of the present disclosure are directed towards a method for layout generation. The method generally includes: receiving one or more constraints associated with a layout of circuit blocks, the one or more constraints including at least one of a level of isolation or a distance between at least two of the circuit blocks; parsing the one or more constraints to generate input data for a layout generation component based on the one or more constraints; generating one or more parameters of the layout based on the input data via the layout generation component; and outputting the one or more parameters.

Certain aspects of the present disclosure are directed towards an apparatus for layout generation. The apparatus generally includes memory and one or more processors coupled to the memory and configured to: receive one or more constraints associated with a layout of circuit blocks, the one or more constraints including at least one of a level of isolation or a distance between at least two of the circuit blocks; parse the one or more constraints to generate input data for a layout generation component based on the one or more constraints; generate one or more parameters of the layout based on the input data via the layout generation component; and output the one or more parameters.

Certain aspects of the present disclosure are directed towards a non-transitory computer-readable medium having instructions stored thereon, that when executed by one or more processors, cause the one or more processors to: receive one or more constraints associated with a layout of circuit blocks, the one or more constraints including at least one of a level of isolation or a distance between at least two of the circuit blocks; parse the one or more constraints to generate input data for a layout generation component based on the one or more constraints; generate one or more parameters of the layout based on the input data via the layout generation component; and output the one or more parameters.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device that includes various circuit blocks, in which aspects of the present disclosure may be practiced.

FIG. 2 illustrates example operations for layout generation, in accordance with certain aspects of the present disclosure.

FIG. 3 illustrates an example implementation of a layout generation tool, in accordance with certain aspects of the present disclosure.

FIG. 4 is a table illustrating example constraints that may be provided to a layout generation tool as an input file, in accordance with certain aspects of the present disclosure.

FIG. 5 is a table illustrating example groupings of circuit blocks, in accordance with certain aspects of the present disclosure.

FIG. 6 is a table illustrating example isolation specifications between circuit block types, in accordance with certain aspects of the present disclosure.

FIG. 7 is a flow diagram illustrating example operations for layout generation, in accordance with certain aspects of the present disclosure.

FIG. 8 depicts aspects of an example computing device.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward apparatus and techniques for generating a layout for circuitry, such as an integrated circuit (IC) or printed circuit board (PCB) layout. For example, a floor planning tool may receive one or more constraints with respect to the layout of circuit blocks. The one or more constraints may be, for example, any one or combination of a minimum level of isolation between circuit blocks, minimum distances between circuit blocks, the total area of each circuit block, ranges of lengths for different dimensions of the circuit block (e.g., the aspect ratio of circuit blocks), whether each circuit block is to be placed next to any edge or a particular edge of the layout, and a clearance from each circuit block to the edge. The floor planning tool may be implemented with a solver to generate layout parameters (e.g., aspect ratios and locations) for circuit blocks. The solver may generate the layout parameters that provide a minimum amount of wasted space (e.g., or at least attempts to reduce wasted space) while meeting the one or more constraints. In some aspects, the solver may be implemented using constrained programming (CP) as described in more detail herein. The floor planning tool may also include a parser that receives the one or more constraints and generates input data in a format that the solver can use to generate the layout parameters, as described in more detail herein.

In some aspects, the parser may include an isolation-to-distance solver. The isolation-to-distance solver may be trained to convert a level of isolation between circuit blocks to a distance between the circuit blocks. The training of the isolation-to-distance solver may be performed using previous layout distances and associated isolation measurements. The derived distances may be provided to the solver to generate the layout parameters. The isolation level between any two circuit blocks may be determined based on the types of two circuit blocks, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatus, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

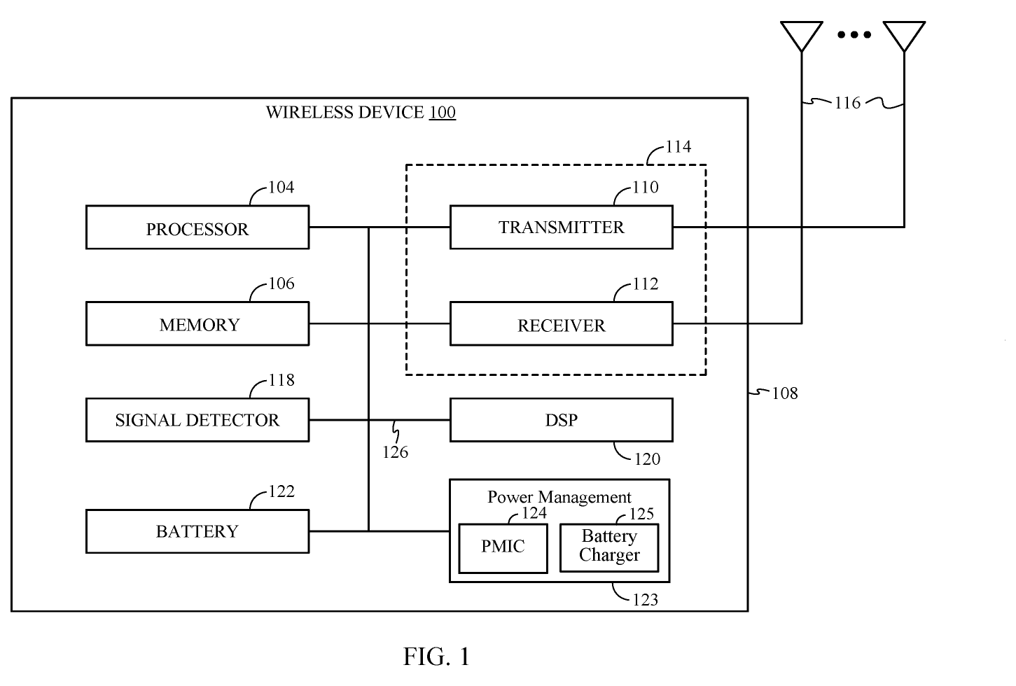

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an automotive device, an Internet of things (IoT) device, a wearable device, etc. For certain aspects, the device 100 may be a foldable device (e.g., a flip phone).

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when another power source—such as a wall adapter or a wireless power charger—is unavailable). The battery 122 may comprise a single cell or multiple cells connected in series and/or in parallel. The device 100 may further include additional independent batteries (not shown). Each of the additional independent batteries may comprise a single cell or multiple cells connected in series and/or in parallel.

The device 100 may also include a power management system 123 for managing the power from the battery 122 (or batteries), a wall adapter, and/or a wireless power charger to the various components of the device 100. The power management system 123 may perform a variety of functions for the device such as DC-to-DC conversion, battery charging, power-source selection, voltage scaling, power sequencing, source mode power, etc. In certain aspects, the power management system 123 may include a power management integrated circuit (power management IC or PMIC) 124 and one or more power supply circuits, such as a battery charger 125, which may be controlled by the PMIC or logic associated with the battery charger, for example. For certain aspects, at least a portion of one or more of the power supply circuits (e.g., at least a portion of the battery charger 125) may be integrated in the PMIC 124. The PMIC 124 and/or the one or more power supply circuits may include at least a portion of a switched-mode power supply (SMPS) circuit, which may be implemented by any of various suitable switched-mode power supply circuit topologies.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

The device 100 may include various circuit blocks implementing the components described herein, such as power supplies and control circuitry for the PMIC. Some circuit blocks may be part of an integrated circuit (IC) or part of a printed circuit board (PCB). Some aspects of the present disclosure are directed towards apparatus and techniques for generating the layout of circuit blocks to reduce wasted space on the layout while meeting various constraints (e.g., designer-defined constraints).

### Example Techniques for Layout Generation

Certain aspects of the present disclosure are directed towards techniques for generating a layout (e.g., also referred to as a “floor plan”) for circuitry (e.g., radio frequency integrated circuit (RFIC), for example that may implement the transceiver 114) in a manner that meets various constraints (e.g., level of isolation between circuit blocks) in an area-efficient manner (e.g., optimizing the layout based on size or dimension requirements and/or reducing (e.g., attempting to minimize or reduce a size of a layout for a circuit as compared to a layout for the circuit generated using conventional techniques) the overall area of the layout (e.g., integrated circuit (IC))). The techniques described herein identify each circuit block’s location and aspect ratio to reduce wasted space on the layout. Certain aspects provide a floor planning tool (e.g., also referred to herein as a “layout generation tool”) to generate a layout for circuit blocks (e.g., digital sub-blocks) based on constraints on the grouping of the circuit blocks and minimum/maximum distances between circuit blocks (e.g., to meet fanout/fanin specifications). A fanout specification refers to a number of inputs of other blocks that can be fed by a circuit block. A fanin specification is essentially a counterpart of the fanout specification and refers to a number of inputs that a circuit block is able to accept (receive) from other blocks. The distance constraints described herein may be used to ensure that fanout/fanin specifications are met. For example, a certain minimum distance between a circuit block and other circuit block(s) may be set to allow for the routing of signals to and from the circuit block.

The layout of some circuitry may be challenging given the concurrent operations of different circuit blocks. For example, circuit blocks such as receivers, transmitters, and phase-locked loops (PLLs) may be present in transceivers and operated concurrently. As a result, a certain level of isolation between the circuit blocks may be specified in order to reduce the level of interference between the circuit blocks. As described, the layout generation tool may generate the layout to optimize total area consumption while meeting various constraints such as the isolation between circuit blocks, as described in more detail herein.

Traditionally, the trade-off between reducing area consumption and increasing the isolation between circuit blocks has been managed through the expertise of human designers, often involving extensive floor planning meetings and discussions. The increasing complexity of layouts, driven by the growing number of circuit blocks on modern layouts, poses a challenge for human designers. Thus, traditional floor planning (e.g., at the chip level) may be an iterative, experience-driven process involving multiple inputs, proposals, and feedback from different designers. This process involves running various simulations and coordinating multiple meetings or discussions between designers before a final layout that meets design specifications is identified.

The techniques and/or devices described herein may reduce the time required to design a circuit layout and potentially improve performance (e.g., power consumption of the device, noise in the various blocks, isolation between blocks, etc.) and/or reduce area. The layout may be designed to meet circuit block area specifications, meet minimum and maximum distances between circuit blocks, meet isolation specifications, and/or provide grouping of circuit blocks that are to be connected via traces. Circuit blocks may be grouped and located in close proximity to reduce power consumption (e.g., due to reduction of losses with decreased trace length) and reduce noise on sensitive signals.

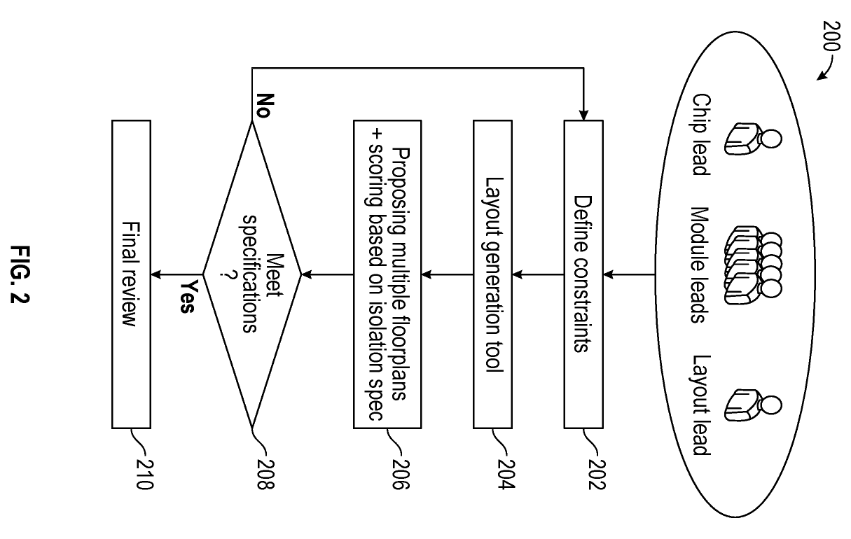

FIG. 2 illustrates example operations 200 for layout generation, in accordance with certain aspects of the present disclosure. The operations 200 may be performed, for example, by a layout generation tool and one or more designers, as described herein.

At block 202, one or more designers, such as a chip lead, module lead, and/or layout lead, may define one or more constraints for the layout generation tool. The constraints may include isolation between circuit blocks, an initial layout area (e.g., die area), the minimum total area of each circuit block, lower/upper bounds for horizontal and vertical dimensions of each circuit block, whether each circuit block is to be placed next to an edge or a particular edge of the floor plan, and/or clearance between the circuit block and the edge. The one or more constraints may be provided to the layout generation tool at block 204 to generate the layout. In some aspects, the layout generation tool may generate multiple candidate layouts at block 206 that meet the one or more constraints while reducing wasted space on the layout. At block 206, the multiple layouts may be scored for various metrics, such as how well each layout meets the one or more constraints or the amount of wasted space on the layout. The scoring may be an output provided by the layout generation tool at block 206, in some cases, but any suitable scoring technique (e.g., manual scoring) may be used. For example, each layout may be given a score with regard to how much isolation is provided between the circuit blocks.

At block 208, the one or more designers may identify whether the layouts meet one or more specifications for the layout. The one or more specifications may include various constraints (e.g., low-level constraints) that were not included as part of the constraints identified at block 202 and provided to the layout generation tool at block 204. For example, a specification (e.g., constraint) with regard to a distance between each circuit block and a particular trace (e.g., routing) may be checked at block 208. Suppose the layouts provided by the layout generation tool do not meet specifications. In that case, the one or more constraints may be redefined (e.g., adjusted) at block 202. The layout generation tool may generate candidate layouts at block 204 until one or more layouts are identified that meet all specifications. At block 210, a final review may be performed by the one or more designers, where the scoring of the selected layouts is reviewed, any adjustments to the layouts are made, or any simulations are performed to confirm that the layouts meet specifications. A final layout may be selected after the final review at block 210.

In some aspects, the layout generation tool may be implemented via an optimizer or other type of solver to generate a floor plan. One example optimizer that may be implemented includes a constraint programming (CP) solver that uses satisfiability (SAT) methods. A CP-SAT tool may be one of a set of operations research (OR) tools providing libraries to solve real-world problems. CP is a method used to solve combinatorial problems by stating constraints to be satisfied. CP involves variables, domains (e.g., possible values for the variables), and constraints (e.g., rules that restrict the values the variables can take). SAT (e.g., Boolean satisfiability problem) solvers determine if there exists an assignment of variables that makes a given Boolean formula true. CP-SAT combines CP techniques with SAT solving to handle complex constraints more efficiently. CP-SAT leverages the strengths of both CP and SAT solving. CP-SAT uses CP to model a problem and SAT solving to find solutions to the problem, making CP-SAT powerful for solving large-scale and complex optimization problems. The layout generation tool described herein may convert different layout constraints such as minimum distance between blocks, or non-overlapping placement (e.g., placement such that circuit blocks do not overlap) to mathematical formulas and generate a layout score function based on user-defined constraints (e.g. meeting isolation specifications between blocks and minimizing wasted area) for the optimizer (e.g., the CP-SAT solver). Then the optimizer attempts to find the optimal placement which increases (e.g., maximizes) the layout score function while satisfying the defined constraints by smartly searching within all the possible floorplans.

The constraints may be parsed to generate input data to the optimizer such that the optimizer can provide the one or more candidate floor plans that meet the constraints described herein. In some examples, the layout generation tool may employ a CP-SAT tool as the engine to solve the layout generation problem to meet the constraints described herein while reducing (e.g., minimizing) area consumption (e.g., reducing wasted space on the layout). The optimizer may provide a layout that maximizes the layout score (e.g., scoring in terms of how well the constraints are met, as described) while minimizing the total chip area, striking a balance between performance and cost-efficiency.

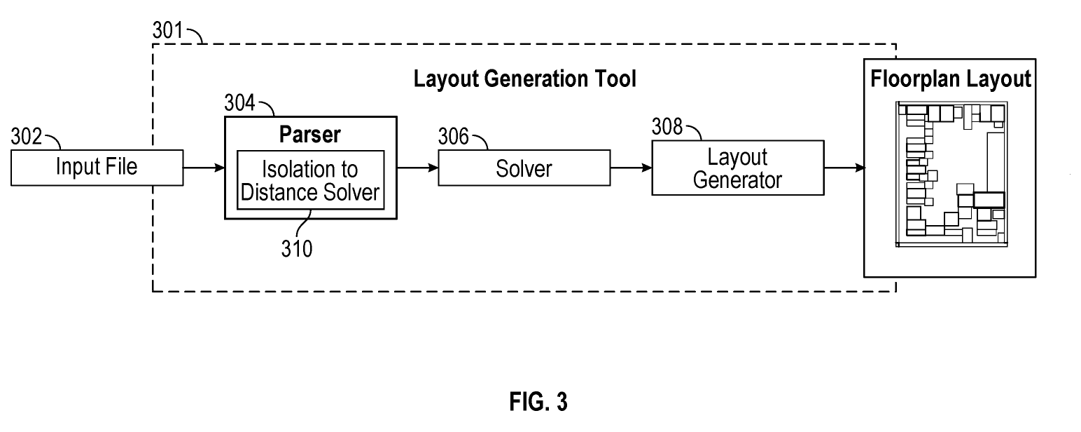

FIG. 3 illustrates an example implementation of a layout generation tool 301, which may be an example of the layout generation tool described above, in accordance with certain aspects of the present disclosure. As shown, the layout generation tool 301 may include a parser 304 that receives an input file 302 defining the one or more constraints described herein. The parser 304 may convert the constraints to data in a format that can be used by solver 306 to generate layout parameters. For example, the parser 304 may generate weights for an objective function representing the isolation between circuit blocks. The objective function and other constraints may be provided to the solver 306. The solver 306 may be implemented using the CP-SAT tool described herein or any suitable optimizer or machine learning (ML) model, such as an ML model trained on previous layouts and associated measurements to generate layout parameters. The objective function may be a linear equation used to represent and solve problems in linear programming, such as the problem of minimizing area while meeting constraints, such as the isolation between circuit blocks. The ML model may be trained based on previous floor plans with known parameters such as isolation between circuit blocks, total area of each circuit block, aspect ratios, groupings, and/or edge constraints as described herein. In some examples, the ML model is a regression model.

In some aspects, the parser 304 may include an isolation-to-distance solver 310. Solver 310 may be an ML model trained to identify minimum distances between circuit blocks based on isolation specifications. For example, a series of known designs with measured distances between circuit blocks and associated isolations may be used to train the solver 310 to convert each level of isolation (e.g., in dBs) to a distance. In some aspects, the calculation for isolation-to-minimum-distance specifications may rely on an empirical equation derived from isolation data obtained from known floor plans.

The constraints, such as the distances between circuit blocks, total area of each circuit block, ranges of aspect ratios of circuit blocks, groupings of circuit blocks, and/or edge constraints of circuit blocks, may be provided to the solver 306. As described, the solver 306 may be a CP-SAT tool or an optimizer or other ML model trained to generate a floor plan that reduces wasted area while meeting the constraints described herein. The solver 306 may provide layout parameters, such as dimensions (e.g., aspect ratios) of circuit blocks and coordinates (e.g., locations) of circuit blocks on a layout to a layout generator 308. The solver 306 may also indicate an objective value (e.g., maximized layout score function) associated with generating the layout parameters. The goal of the solver is to increase (e.g., maximize) the layout score function in an attempt to provide the optimal layout floorplan. In the case that the tool finds multiple solutions, the objective value associated with those solutions can be used to rank the quality of the floorplan. Based on the layout data, the layout generator 308 may generate a floor plan layout as shown.

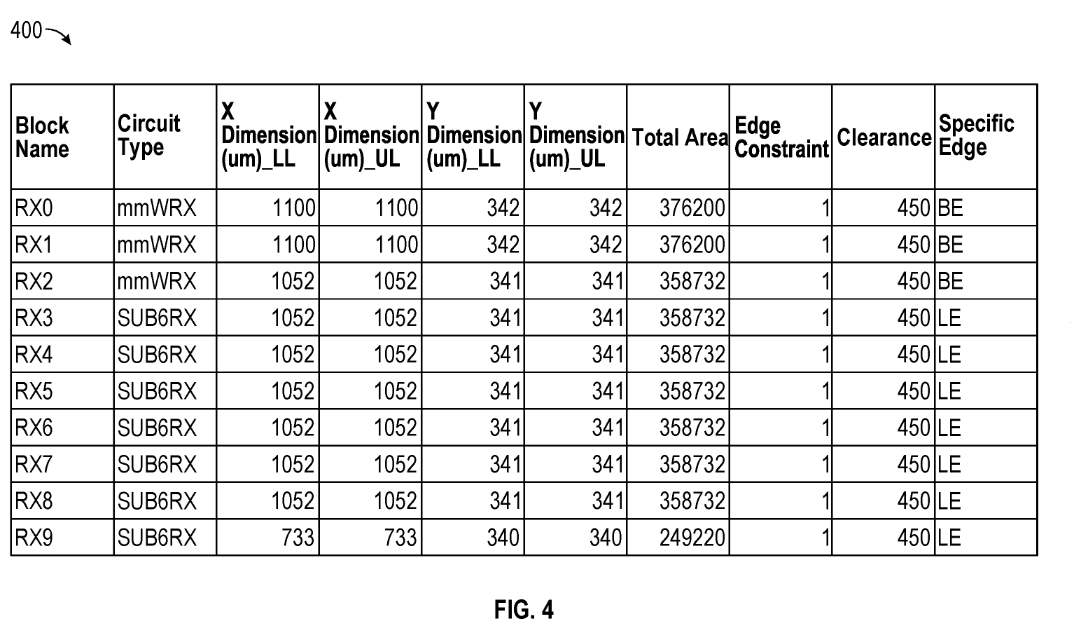

FIG. 4 is a table 400 illustrating example constraints that may be provided to the layout generation tool 301 as an input file, in accordance with certain aspects of the present disclosure. Examples in FIGS. 4-6 are provided in the context of designing a transceiver chip, but it will be understood that other chips or circuits may be designed using the techniques described herein. As shown in FIG. 4, the input file may include names of circuit blocks such as various receivers labeled “RX0” to “RX9.” For each circuit block, the input file may define the circuit type. For example, RX0 to RX2 may be millimeter wave receivers (or receivers for signals derived from millimeter waves, such as intermediate frequency or other downconverted signals) labeled “mmWRX,” and RX3 to RX9 may be sub-6 GHz receivers labeled “SUB6RX.” The aspect ratios of each circuit block may also be defined using lower and upper bounds (e.g., limits). For example, the X dimension length of each circuit block may be indicated as a range within a lower limit (LL) and an upper limit (UL) in microns labeled “X Dimension (um)_LL” and “X Dimension (um)_UL.” Similarly, the Y dimension length of each circuit block may be indicated as a range within a lower limit (LL) and an upper limit (UL) in microns labeled “Y Dimension (um)_LL” and “Y Dimension (um)_UL.” In addition or alternatively, the minimum total area of each circuit block may be indicated. The minimum total area or aspect ratios may be identified as constraints based on the circuitry that each circuit block is to support. In some examples, the X and Y dimensions may be switched by the solver 306, for example such that the block is rotated in the generated layout with respect to the provided dimensions. In some examples, the circuit blocks may have a shape other than rectangular (which may be specified in the constraints, or may be up to the layout generation tool to decide). The edge constraint for each circuit block may be indicated. For example, a “1” may indicate that the circuit block should be placed by an edge (e.g., within a maximum distance to any of the four edges of the layout), and “0” otherwise. For each circuit block, clearance to the edge (e.g., distance from the edge) may be indicated (e.g., in microns). The input file may also indicate whether each circuit block is to be placed by a specific edge, such as the left edge (LE), the right edge (RE), the bottom edge (BE), or the top edge (TE) of the layout. While these fields are provided as examples, it will be understood that one or more of the fields may be omitted altogether or that a value for a certain field for a certain block may be blank or otherwise indicated as not having a particular constraint. For example, the RX8 circuit block may not include any entry in the specific edge column, thereby indicating that placement near a particular edge isn’t required. Additional fields (not illustrated) may also be included.

Although not shown in FIG. 4, another constraint that the layout generation tool 301 may be provided or configured with may include non-overlapping placement. In other words, the layout generation tool 301 identifies the placement and aspect ratios of the circuit blocks such that the circuit blocks do not overlap in the layout.

In some aspects, the layout generation tool 301 may explore different aspect ratios for each circuit block based on the ranges defined in the input file while keeping the total area for that block fixed. By exploring different aspect ratios, the layout generation tool 301 may identify a specific aspect ratio for each circuit block that minimizes (or at least reduces) the wasted space on the layout while meeting the various constraints such as isolation or distance between circuit blocks.

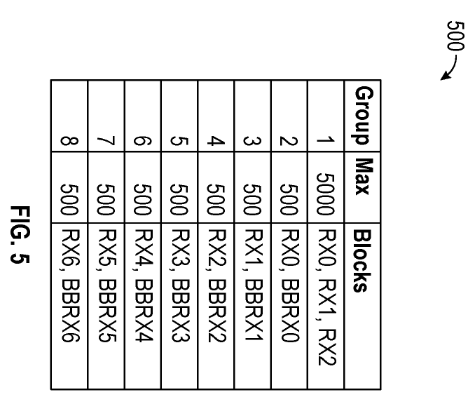

FIG. 5 is a table 500 illustrating the grouping of circuit blocks, which may also be provided to the layout generation tool 301 as an input file, in accordance with certain aspects of the present disclosure. As shown, various groups of circuit blocks may be defined along with a maximum distance between the blocks in each group. For instance, in group 1, receivers RX0, RX1, and RX2 may be grouped such that the associated blocks are placed no more than 5000 microns from each other. In group 2, the receiver RX0 may be grouped with a baseband receiver (BBRX0) such that the associated blocks are placed no more than 500 microns from each other. The distances may refer to the distance between edges of the blocks, or to the distance between centers of the blocks, or to any other distance measurement between blocks. RX# refers to a receive path (e.g., block) for RF signals (and potentially signals being downconverted from RF to baseband), while BBRX# refers to a receive path (e.g., block) for baseband signals.

The grouping of circuit blocks may be identified for any suitable reason such as reducing routing distances and reducing current consumption (e.g., reducing losses across long traces). Reducing routing distances may be particularly important for top-level routings, including routing for voltage-controlled oscillator (VCO) signals, routing for crystal oscillator (XO) signals, and/or routing for baseband (BB) signals as the current consumption of these signals may be highly dependent on the associated routing length as a result of parasitic impedances of traces.

In modern radio frequency integrated circuits (RFICs), numerous receivers, transmitters, and phase-locked loop (PLL) circuits may be used to support different standards and technologies, such as diverse carrier aggregation combinations and various frequency bands simultaneously. For proper operation, stringent isolation specifications between the circuit blocks may be followed within the floor plan or chip. An isolation input file may be used to specify the isolation specifications between different circuit block types, in some aspects.

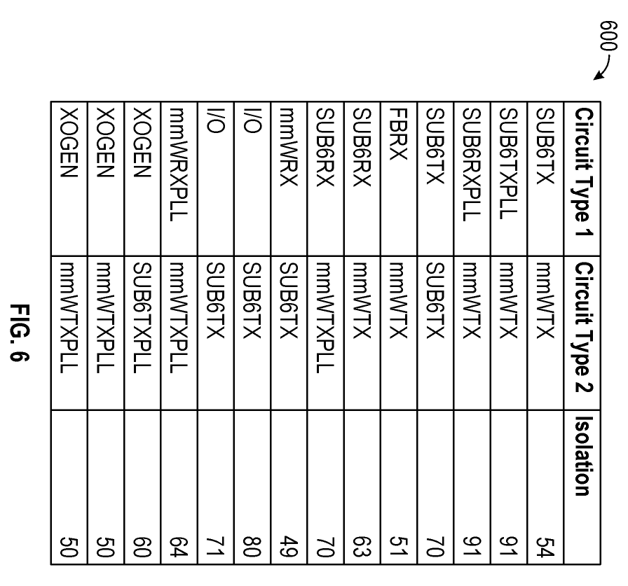

FIG. 6 is a table 600 illustrating isolation specifications between circuit block types, which may also be provided to the layout generation tool 301 as an input file, in accordance with certain aspects of the present disclosure. The isolation specifications between different circuit block types may be determined based on testing and simulations. For example, the electromagnetic (EM) properties of circuit blocks (e.g., the sensitivity of a circuit block to EM interference or a circuit block’s potential for EM interference with other circuitry) may be considered to determine the isolation specifications for that circuit block or between the circuit block and other circuit blocks. For example, a 54 dB isolation may be specified between a sub-6 GHz transmitter (SUB6TX) and a millimeter wave transmitter (mmWTX). The isolation specifications between circuit block types may be used by the layout generation tool 301 to determine the isolation between circuit blocks. The isolation-to-distance solver 310 may then be used to determine the minimum distances between circuit blocks based on the isolation specifications, as described herein. The table 600 includes pairs of circuit types. In other examples, pairs of specific circuit blocks (e.g., similar to the specific circuit blocks in FIG. 5) may be included in the table 600, or one or more specific circuit blocks and one or more circuit types (e.g., RX0 and SUB6TXPLL) may be paired. More circuit blocks or types than two may also be included, where the recited isolation is observed between any two of the more than two blocks or circuit types. Similarly, the table 500 may include circuit types (similar to what’s included in FIG. 6) instead of a specific circuit block.

FIGS. 4-6 illustrate example tables 400, 500, 600. In other examples, data from two or more of these tables may be combined or data may be separated out into additional tables or input files. A fewer or greater number of input tables may be utilized, less or additional information or constraints may be provided in the input files, and/or the data may be combined or separated or otherwise presented in a different format.

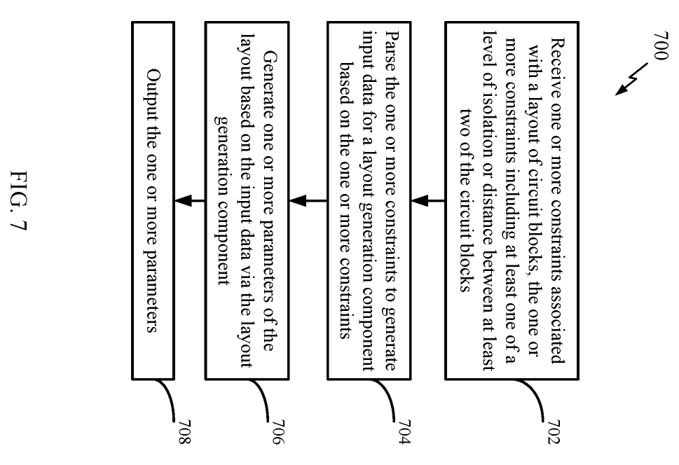

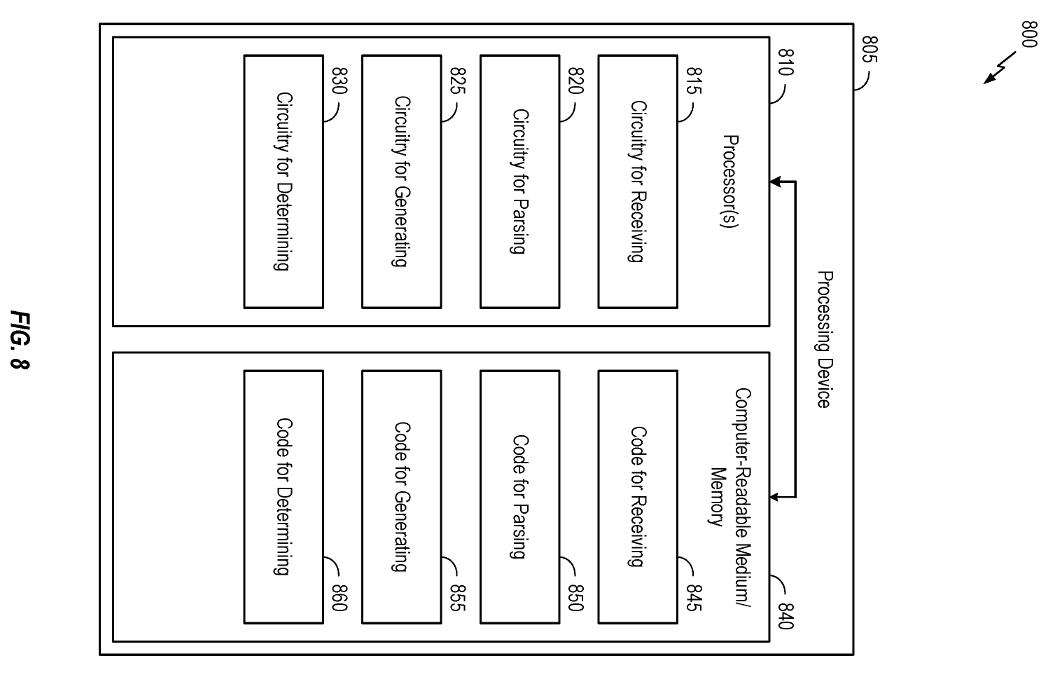

FIG. 7 is a flow diagram illustrating example operations 700 for layout generation, in accordance with certain aspects of the present disclosure. The operations 700 may be performed, for example, by a processing device such as the processing device 805 of FIG. 8 which may implement the layout generation tool 301 of FIG. 3.

At block 702, the processing device may receive one or more constraints associated with a layout of circuit blocks, the one or more constraints including at least one of a level of isolation or a distance between at least two of the circuit blocks. In some aspects, the processing device may determine the level of isolation between the at least two circuit blocks based on a circuit type of each of the at least two circuit blocks.

At block 704, the processing device parses the one or more constraints to generate input data for a layout generation component (e.g., layout generation tool 301) based on the one or more constraints. The layout generation component may be implemented via a constrained programming (CP) solver or another optimizer or ML model. In some aspects, parsing the one or more constraints may include generating weights for an objective function used by a model of the layout generation component to generate the layout.

At block 706, the processing device generates one or more parameters of the layout based on the input data via the layout generation component. In some aspects, the one or more parameters may include at least one of coordinates or dimensions of each of the circuit blocks. At block 708, the processing device may output the one or more parameters. For example, the one or more parameters may be output to a layout generator (e.g., layout generator 308) to generate a floor plan. In some aspects, the one or more parameters or the associated floor plan may be output to a fab house or a manufacturer to fabricate an IC or PCB according to the one or more parameters.

In some aspects, parsing the one or more constraints may include converting the level of isolation to the distance between the at least two of the circuit blocks. The level of isolation may be converted to the distance using an isolation-to-distance model trained based on isolation and distance data from other circuit layouts.

In some aspects, the one or more constraints further include at least one of: a range of lengths for a first dimension of each of the circuit blocks; a range of lengths for a second dimension of each of the circuit blocks; a minimum total area of each of the circuit blocks; a grouping of the circuit blocks; whether each of the circuit blocks is to be placed next to any edge of the layout; whether each of the circuit blocks is to be placed next to a particular edge of the layout; or a clearance of each of the circuit block to the any edge or the particular edge of the layout. The grouping of the circuit blocks may include a minimum distance between at least two of the circuit blocks.

It will be understood that the techniques and/or devices described herein can be used to design a layout for any number of different circuits or devices. For example, the techniques and/or devices described herein can be used to design analog or mixed-signal circuits for transceivers (e.g., the transceiver 114) in a phone or consumer device, or in a base station or access point (AP) or consumer premises equipment (CPE). Other analog or mixed-signal circuits that may be designed using the techniques and/or devices described herein include the signal detector 118, power management system 123, PMIC 124, battery charger 125, etc. The techniques and/or devices described herein may be used to design digital circuits, such as for the processor 104, memory 106, DSP 120, another type of CPU, GPU, NPU, etc. The techniques and/or devices may be used to design circuit layouts for circuits not included in the device 100. The techniques and/or devices described herein may be used for floor planning at different levels of design (transistor level/sub-block level/chip top-level/ PCB level), for example to most efficiently utilize area while meeting performance requirements.

In one example, the techniques and/or devices described herein may be used to determine a layout for a transceiver chip. Certain example aspects related to such functionality are described above and in the figures. In such example, the circuit blocks may include receive or transmit chains for RF signals for a wide area network, local area network, personal network, or satellite network, where the blocks may be different for different frequency ranges (e.g., below 3GHz, between 3 and 7 GHz, between7and 20 GHz, above 20 GHz, etc.); receive or transmit chains for baseband signals for any such networks; a feedback receiver; analog to digital (ADC) or digital to analog (DAC) circuits; bias circuits; clock or timing signal generation or compensation (e.g., for a crystal oscillator, VCO, PLL, etc.); diplexer, duplexer, triplexer, multiplexer, and/or switch circuits, etc.; interface circuits to other chips (e.g., a modem to transceiver interface); etc.

While circuits for certain functions have been described to facilitate understanding, the techniques and/or devices described herein can be used to generate a layout for any suitable circuit serving any functionality. For example, for a CPU, the circuit blocks described herein may include an arithmetic logic unit (ALU), instruction decoder, cache memory, a control unit, or a memory controller, to name a few. As another example, for a GPU, the circuit blocks may include a ray tracing core, a tensor core, a texture mapping unit, or a frame buffer.

In some such transceiver examples, the layout generation tool described herein may be used to determine positions and aspect ratios of analog, mixed-signal, and interface circuit blocks, and the area between these blocks is then utilized to implement digital circuitry. In some examples, a minimum area or set of dimensions identified for implementation of the digital circuitry is provided as a constraint (e.g., in an input file 302) to the layout generation tool 301. In other examples, a subset or all of the digital blocks are included in an input file 302 provided to the layout generation tool 301 such that the tool will arrange analog, mixed-signal, and digital circuitry.

FIG. 8 depicts aspects of an example computing device 800. The computing device 800 may include a processing device 805 configured to perform processing functions such as the operations described herein for layout generation, for example block 206 in FIG. 2, the layout generation tool 301 or subcomponents thereof in FIG. 3, operations 700 in FIG. 7, etc.

The processing device 805 includes one or more processors 810 and computer-readable medium/memory 840 that stores code (e.g., executable instructions), such as code for receiving 845, code for parsing 850, code for generating 855, and code for determining 860. Processing of the code for receiving 845, code for parsing 850, code for generating 855, and code for determining 860 may cause the computing device 800 to perform the operations 700 described with respect to FIG. 7 or any aspect related to operations 700.

The one or more processors 810 include circuitry configured to implement (e.g., execute) the code stored in the computer-readable medium/memory 840, including circuitry such as circuitry for receiving 815, circuitry for parsing 820, circuitry for generating 825, and circuitry for determining 830. Processing with circuitry for receiving 815, circuitry for parsing 820, circuitry for generating 825, and circuitry for determining 830 may cause the computing device 800 to perform the operations 700 described with respect to FIG. 7 or any aspect related to operations 700. Various components of the computing device 800 may provide means for performing the operations 700 described with respect to FIG. 7 or any aspect related to operations 700.

### Example Aspects

In addition to the various aspects described above, specific combinations of aspects are within the scope of the disclosure, some of which are detailed below:

Aspect 1: A method for layout generation, comprising: receiving one or more constraints associated with a layout of circuit blocks, the one or more constraints including at least one of a level of isolation or a distance between at least two of the circuit blocks; parsing the one or more constraints to generate input data for a layout generation component based on the one or more constraints; generating one or more parameters of the layout based on the input data via the layout generation component; and outputting the one or more parameters.

Aspect 2: The method of Aspect 1, wherein parsing the one or more constraints includes converting the level of isolation to the distance between the at least two of the circuit blocks.

Aspect 3: The method of Aspect 2, wherein the level of isolation is converted to the distance using an isolation-to-distance model trained based on isolation and distance data from other circuit layouts.

Aspect 4: The method according to any of Aspects 1–3, wherein parsing the one or more constraints includes generating weights for an objective function used by a model of the layout generation component to generate the layout.

Aspect 5: The method according to any of Aspects 1–4, wherein the one or more parameters include at least one of coordinates or dimensions of each of the circuit blocks.

Aspect 6: The method according to any of Aspects 1–5, wherein the one or more constraints further include at least one of: a range of lengths for a first dimension of each of the circuit blocks; a range of lengths for a second dimension of each of the circuit blocks; a minimum total area of each of the circuit blocks; a grouping of the circuit blocks; whether each of the circuit blocks is to be placed next to any edge of the layout; whether each of the circuit blocks is to be placed next to a particular edge of the layout; or a clearance of each of the circuit blocks to the any edge or the particular edge of the layout.

Aspect 7: The method of Aspect 6, wherein the grouping of the circuit blocks includes a maximum distance between at least two of the circuit blocks.

Aspect 8: The method of Aspect 6 or 7, further comprising determining the level of isolation between the at least two of the circuit blocks based on a circuit type of each of the at least two of the circuit blocks.

Aspect 9: The method according to any of Aspects 1–8, wherein the layout generation component is implemented via a constrained programing (CP) solver.

Aspect 10: An apparatus for layout generation, comprising: memory; and one or more prcessors coupled to the memory and configured to: receive one or more constraints associated with a layout of circuit blocks, the one or more constraints including at least one of a level of isolation or a distance between at least two of the circuit blocks; parse the one or more constraints to generate input data for a layout generation component based on the one or more constraints; generate one or more parameters of the layout based on the input data via the layout generation component; and output the one or more parameters.

Aspect 11: The apparatus of Aspect 10, wherein, to parse the one or more constraints, the one or more processors are configured to convert the level of isolation to the distance between the at least two of the circuit blocks.

Aspect 12: The apparatus of Aspect 11, wherein the level of isolation is converted to the distance using an isolation-to-distance model trained based on isolation and distance data from other circuit layouts.

Aspect 13: The apparatus according to any of Aspects 10–12, wherein, to parse the one or more constraints, the one or more processors are configured to generate weights for an objective function used by a model of the layout generation component to generate the layout.

Aspect 14: The apparatus according to any of Aspects 10–13, wherein the one or more parameters include at least one of coordinates or dimensions of each of the circuit blocks.

Aspect 15: The apparatus according to any of Aspects 10–14, wherein the one or more constraints further include at least one of: a range of lengths for a first dimension of each of the circuit blocks; a range of lengths for a second dimension of each of the circuit blocks; a minimum total area of each of the circuit blocks; a grouping of the circuit blocks; whether each of the circuit blocks is to be placed next to any edge of the layout; whether each of the circuit blocks is to be placed next to a particular edge of the layout; or a clearance of each of the circuit blocks to the any edge or the particular edge of the layout.

Aspect 16: The apparatus of Aspect 15, wherein the grouping of the circuit blocks include a maximum distance between at least two of the circuit blocks.

Aspect 17: The apparatus of Aspect 15 or 16, further comprising determining the level of isolation between the at least two of the circuit blocks based on a circuit type of each of the at least two of the circuit blocks.

Aspect 18: The apparatus according to any of Aspects 10-17, wherein the layout generation component is implemented via a constrained programing (CP) solver.

Aspect 19: A non-transitory computer-readable medium having instructions stored thereon, that when executed by one or more processors, cause the one or more processors to: receive one or more constraints associated with a layout of circuit blocks, the one or more constraints including at least one of a level isolation or distance between at least two of the circuit blocks; parse the one or more constraints to generate input data for a layout generation component based on the one or more constraints; generate one or more parameters of the layout based on the input data via the layout generation component; and output the one or more parameters.

Aspect 20: The non-transitory computer-readable medium of Aspect 19, wherein, to parse the one or more constraints, the instructions further cause the one or more processors to convert the level of isolation to the distance between the at least two of the circuit blocks.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A method for layout generation, comprising:
receiving one or more constraints associated with a layout of circuit blocks, the one or more constraints including at least one of a level of isolation or a distance between at least two of the circuit blocks;
parsing the one or more constraints to generate input data for a layout generation component based on the one or more constraints;
generating one or more parameters of the layout based on the input data via the layout generation component; and
outputting the one or more parameters.

2. The method of claim 1, wherein parsing the one or more constraints includes converting the level of isolation to the distance between the at least two of the circuit blocks.

3. The method of claim 2, wherein the level of isolation is converted to the distance using an isolation-to-distance model trained based on isolation and distance data from other circuit layouts.

4. The method of claim 1, wherein parsing the one or more constraints includes generating weights for an objective function used by a model of the layout generation component to generate the layout.

5. The method of claim 1, wherein the one or more parameters include at least one of coordinates or dimensions of each of the circuit blocks.

6. The method of claim 1, wherein the one or more constraints further include at least one of:
a range of lengths for a first dimension of each of the circuit blocks;
a range of lengths for a second dimension of each of the circuit blocks;
a minimum total area of each of the circuit blocks;
a grouping of the circuit blocks;
whether each of the circuit blocks is to be placed next to any edge of the layout;
whether each of the circuit blocks is to be placed next to a particular edge of the layout; or
a clearance of each of the circuit blocks to the any edge or the particular edge of the layout.

7. The method of claim 6, wherein the grouping of the circuit blocks includes a maximum distance between at least two of the circuit blocks.

8. The method of claim 6, further comprising determining the level of isolation between the at least two of the circuit blocks based on a circuit type of each of the at least two of the circuit blocks.

9. The method of claim 1, wherein the layout generation component is implemented via a constrained programing (CP) solver.

10. An apparatus for layout generation, comprising:
memory; and
one or more processors coupled to the memory and configured to:
receive one or more constraints associated with a layout of circuit blocks, the one or more constraints including at least one of a level of isolation or a distance between at least two of the circuit blocks;
parse the one or more constraints to generate input data for a layout generation component based on the one or more constraints;
generate one or more parameters of the layout based on the input data via the layout generation component; and
output the one or more parameters.

11. The apparatus of claim 10, wherein, to parse the one or more constraints, the one or more processors are configured to convert the level of isolation to the distance between the at least two of the circuit blocks.

12. The apparatus of claim 11, wherein the level of isolation is converted to the distance using an isolation-to-distance model trained based on isolation and distance data from other circuit layouts.

13. The apparatus of claim 10, wherein, to parse the one or more constraints, the one or more processors are configured to generate weights for an objective function used by a model of the layout generation component to generate the layout.

14. The apparatus of claim 10, wherein the one or more parameters include at least one of coordinates or dimensions of each of the circuit blocks.

15. The apparatus of claim 10, wherein the one or more constraints further include at least one of:
a range of lengths for a first dimension of each of the circuit blocks;
a range of lengths for a second dimension of each of the circuit blocks;
a minimum total area of each of the circuit blocks;
a grouping of the circuit blocks;
whether each of the circuit blocks is to be placed next to any edge of the layout;
whether each of the circuit blocks is to be placed next to a particular edge of the layout; or
a clearance of each of the circuit blocks to the any edge or the particular edge of the layout.

16. The apparatus of claim 15, wherein the grouping of the circuit blocks include a maximum distance between at least two of the circuit blocks.

17. The apparatus of claim 15, wherein the one or more processors is configured to determine the level of isolation between the at least two of the circuit blocks based on a circuit type of each of the at least two of the circuit blocks.

18. The apparatus of claim 10, wherein the layout generation component is implemented via a constrained programing (CP) solver.

19. A non-transitory computer-readable medium having instructions stored thereon, that when executed by one or more processors, cause the one or more processors to:
receive one or more constraints associated with a layout of circuit blocks, the one or more constraints including at least one of a level isolation or distance between at least two of the circuit blocks;
parse the one or more constraints to generate input data for a layout generation component based on the one or more constraints;
generate one or more parameters of the layout based on the input data via the layout generation component; and
output the one or more parameters.

20. The non-transitory computer-readable medium of claim 19, wherein, to parse the one or more constraints, the instructions further cause the one or more processors to convert the level of isolation to the distance between the at least two of the circuit blocks.
